(19) United States
(12) Patent Application Publication
(10) Pub. No.: US 2007/0059926 A1
(43) Pub. Date: Mar. 15, 2007

(54) Method for fabricating semiconductor device including resist flow process and film coating process

(75) Inventor: Jae Chang Jung, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Gyeonggi-do (KR)

(21) Appl. No.: 11/479,502

(22) Filed: Jun. 30, 2006

(30) Foreign Application Priority Data
Sep. 13, 2005 (KR) 10-2005-0085255

(51) Int. Cl. H01L 21/44

(52) U.S. Cl. 438/670

(57) ABSTRACT

A method for fabricating a semiconductor device wherein a photoresist pattern is formed over an underlying layer, followed by a resist flow process and a coating treatment process, thereby obtaining a photoresist pattern reduced to the same size regardless of pattern density of photoresist. As a result, the disclosed method is useful in all semiconductor fabricating processes for forming a fine pattern of more than a resolution of an exposure.

### BACKGROUND OF THE DISCLOSURE

1. Field of the Disclosure

The disclosure generally relates to a method for fabricating a semiconductor device that includes i) forming a photoresist pattern and then ii) performing both a resist flow process (hereinafter, referred to as “RFP”) and a coating treatment process thereon, thereby obtaining a uniformly reduced photoresist pattern regardless of the photoresist pattern density.

2. Brief Description of Related Technology

As the fields of application of semiconductor devices have expanded, there has been a need to fabricate high-capacity memory devices with improved integrity. Semiconductor fabricating processes necessarily include a lithography process for forming a line pattern (such as a gate line and a bit line), or a contact hole pattern (such as a bit line contact).

In order to form a critical dimension (CD) below 0.1 μm, the lithography process utilizes an exposer with deep ultra violet (DUV) light sources of short wavelength such as ArF (193 nm) or VUV (157 nm) instead of long wavelength light sources such as i-line or KrF (248 nm).

In addition, in order to obtain a fine contact hole pattern having the resolution over the exposer, (i) RFP (Japanese Journal of Applied Physics. Vol. 37 (1998) pp. 6863-6868) or (ii) a coating treatment process with SAFIER™ (Shrink Assist Film for Enhanced Resolution) materials produced by Tokyo Ohka Kogyo Co., Ltd. (Advances in Resist Technology and Processing XXI. Edited by Sturtevant, John L. Proceedings of the SPIE, volume 5376, pp. 533-540 (2004), the disclosure of which is hereby incorporated by reference) have been developed.

(i) According to the RFP, thermal energy is applied to the photoresist pattern obtained from a photolithography process over a glass transition temperature (Tg) for a predetermined time so that photoresist may flow thermally. As a result, the size of the photoresist contact hole pattern is reduced.

Even when uniform thermal energy is transmitted over the whole surface of the photoresist during the RFP, the photoresist flows from the lower portion more rapidly than from the upper or middle portion to cause an over-flowing phenomenon where the upper portion of the pattern becomes wider than the lower portion of the pattern. Furthermore, since photoresist patterns each having different density are formed on the device, the thermal flowing amount of photoresist is different due to density differences. As a result, it is difficult to obtain a reduced pattern having a uniform size.

FIG. 1a and 1b are diagrams illustrating change of a photoresist contact hole pattern size when a conventional RFP is performed.

Referring to FIG. 1a, an exposure and developing processes are performed on the photoresist film 3 over an underlying layer 1, thereby obtaining a photoresist contact hole pattern 5 of 130 nm. Thereafter, a general RFP process is performed on the photoresist contact hole pattern 5 for one minute. As a result, as shown in Fig 1b, while the contact hole pattern 5-1 reduced to 100 nm is formed because the amount of resist that can flow in a region (a) having a higher contact hole density is small, the contact hole pattern 5-2 reduced to 70 nm is formed because the amount of resist that can flow in a region (b) having a lower contact hole density is large.

(ii) According to the coating treatment process, coating materials such as SAFIER™ material are coated on the whole photoresist pattern obtained from a photo-lithography process. Then, the resulting structure is heated over the glass transition temperature of the photoresist polymer to reduce the photoresist contact hole pattern.

However, when a coating film is formed over the photoresist pattern, a coating material is filled into numerous contact holes in the region having a high contact hole pattern density so that the coating film is formed in a low thickness. On the other hand, there are a few contact hole to be filled with coating material in the region having a low contact hole pattern density so that the coating film is formed in a high thickness. As a result, even when the same energy is transmitted into the whole surface of the coating film in a subsequent heating treatment process, it is difficult to reduce the photoresist contact hole pattern to have a uniform size due to the coating film thickness difference.

FIG. 2a through 2c are diagrams illustrating change of a photoresist contact hole pattern size when a coating treatment process using conventional SAFIER™ material is performed.

Referring to FIG. 2a, an exposure and developing processes are performed on the photoresist film 23 over an underlying layer 21, thereby obtaining a photoresist contact hole pattern 25 of 130 nm. Thereafter, SAFIER™ material is coated on the photoresist contact hole pattern 25 to form a coating film 27, and the heating treatment process 29 is performed on the resulting structure over a glass transition temperature of the photoresist for more than three minutes. Then, the coating film is removed. As a result, the photoresist contact hole pattern 25-2 reduced to 100 nm is formed in a region (b), while the contact hole pattern 25-1 of 70 nm is formed in the region (a) because the heat transfer effect is higher by the thin coating film in the region (a) having a high contact hole pattern density than of region (b) having a low contact hole pattern density.

When non-uniform patterns are formed by the above-described phenomenon, it is impossible to obtain a sufficient etching margin required to perform a subsequent stable etching process, and the accuracy of pattern critical dimension is degraded to reduce final semiconductor device yield.

### SUMMARY OF THE DISCLOSURE

Disclosed herein is a method for fabricating a semiconductor device that comprises RFP and a coating treatment process so that a photoresist contact hole pattern may be reduced uniformly regardless of photoresist pattern density.

### BRIEF DESCRIPTION OF THE DRAWING FIGURES

For a more complete understanding of the disclosure, reference should be made to the following detailed description and accompanying drawings, wherein:

FIGS. 1a and 1b are diagrams illustrating a conventional method for fabricating a semiconductor device using a resist flow process;

FIG. 2a through 2c are diagrams illustrating a conventional method for fabricating a semiconductor device using SAFIER™ material;

FIG. 3a through 3d are diagrams illustrating a disclosed method for fabricating a semiconductor device according to Example 1;

FIG. 4a is a SEM photographs illustrating a photoresist pattern of Example 1;

FIG. 4b is a SEM photograph illustrating the photoresist pattern after resist flow process of Example 1;

FIG. 4c is a SEM photograph illustrating the photoresist pattern after coating treatment process of Example 1;

FIG. 5a through 5d are diagrams illustrating a disclosed method for fabricating a semiconductor device according to Example 2;

FIG. 6a is a SEM photographs illustrating a photoresist pattern of Example 2;

FIG. 6b is a SEM photograph illustrating the photoresist pattern after coating treatment process of Example 2; and

FIG. 6c is a SEM photograph illustrating the photoresist pattern after resist flow process of Example 2.

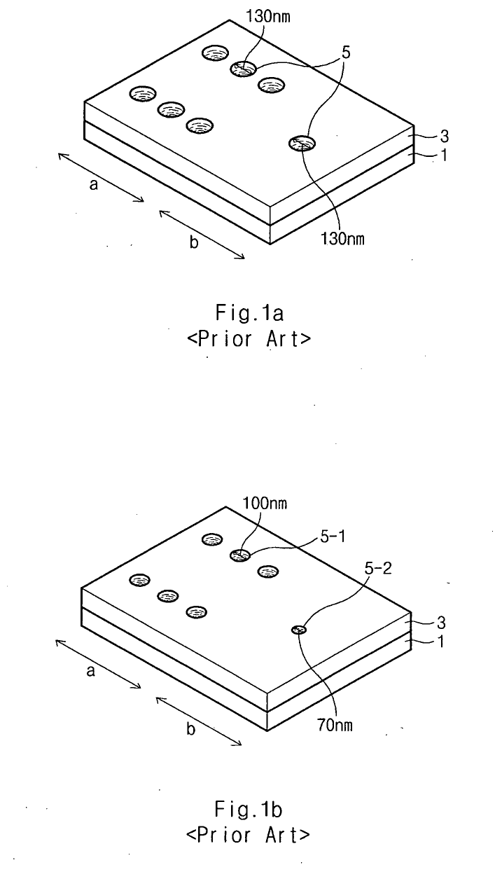

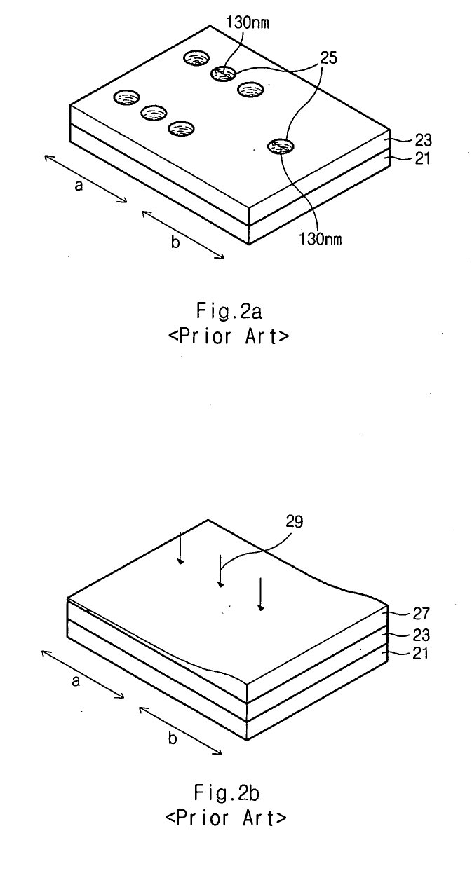

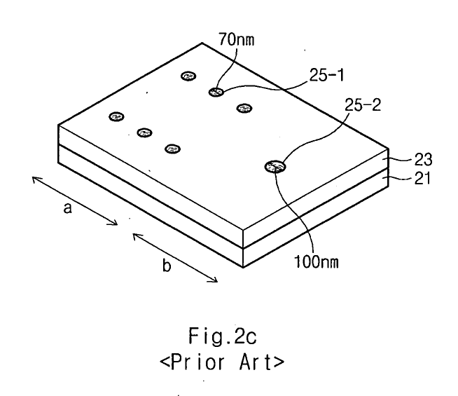

While the disclosed composition and method are susceptible of embodiments in various forms, there are illustrated in the drawing (and will hereafter be described) specific embodiments of the invention, with the understanding that the disclosure is intended to be illustrative, and is not intended to limit the invention to the specific embodiments described and illustrated herein.

### DETAILED DESCRIPTION

The disclosed method for fabricating a semiconductor device using a photolithography process, comprises the steps of: (a) forming a first photoresist pattern; and (b) performing both a resist flow process (RFP) and a coating treatment process to obtain a second photoresist pattern having a higher resolution than that of the first photoresist pattern.

Preferably, the method for fabricating a semiconductor device includes the steps of:

(a) forming a photoresist film over an underlying layer;

(b) performing an exposure and developing process on the photoresist film to form a first photoresist contact hole pattern;

(c) performing RFP on the first photoresist contact hole pattern; and

(d) performing a coating treatment process on the whole surface of the resulting structure to obtain a second photoresist pattern.

The coating treatment process of step (d) preferably includes forming a coating film over the resulting structure of step (c); performing the heating treatment process thereon; and removing the coating film.

The RFP process of step (c) is preferably performed at the glass transition temperature or over the glass transition temperature for a predetermined time, and more preferably performed under process conditions where the minimum photoresist contact hole pattern obtained from the previous process is reduced by about 5% to about 20%. Also, the heating treatment process of coating treatment process of the step (d) is preferably performed under process conditions where the minimum photoresist contact hole pattern obtained from the previous process is reduced by about 5% to about 20%.

Preferably, the coating film has a different dissolving physical property from that of photoresist. Hence, the photoresist film has a different solubility from that of the coating film in the solvent used to remove the coating film. For example, when water is used as a solvent to remove the coating film, the photoresist film has a lower solubility to water while the coating film has a higher solubility to water.

The photoresist film has a lower solubility to water in general. The coating film includes a water-soluble polymer compound having a molecular weight ranging from about 200 to about 50,000 that has a higher solubility to water and can effectively fill in the contact hole pattern; more preferably, a poly(N,N-dimethylacrylamide) compound that has a molecular weight of 15,000 or common SAFIER™ material can be used for coating materials.

The second photoresist pattern obtained by the above-described method is higher than that of the photoresist pattern obtained by using an exposer.

The reduced pattern size in the steps (c) and (d) can be regulated with a treatment time and a temperature of the RFP and with a heating time and a temperature of the coating treatment process.

The disclosed method will be described in detail with reference to the attached drawings.

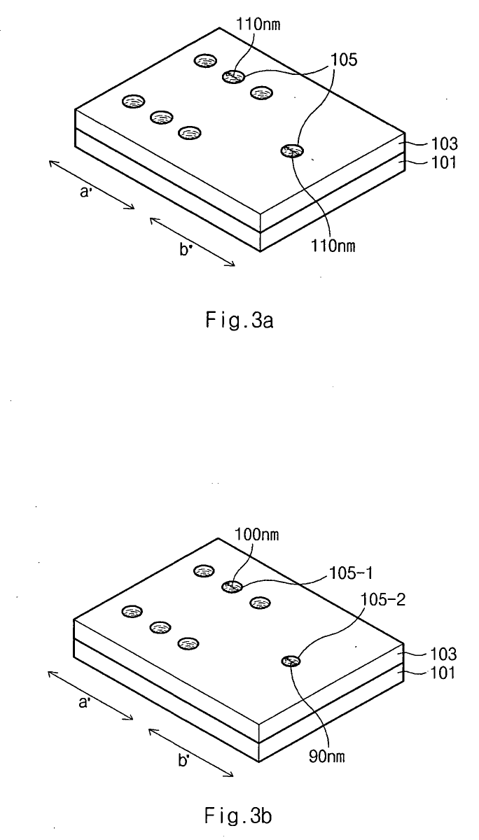

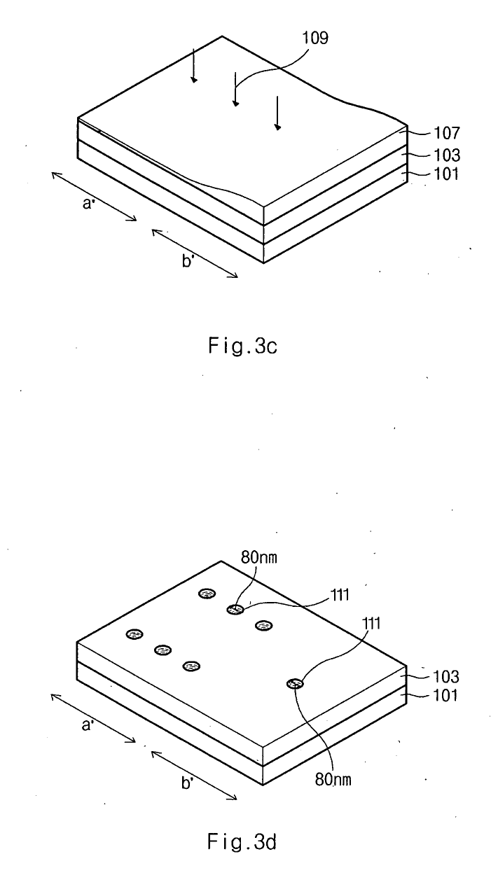

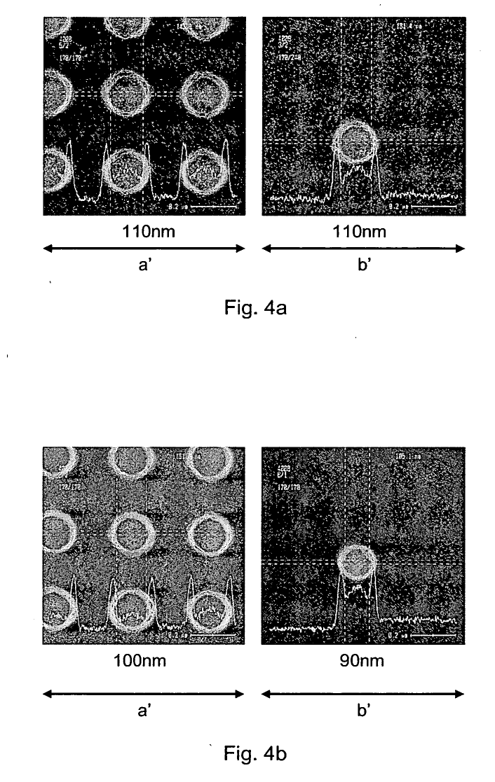

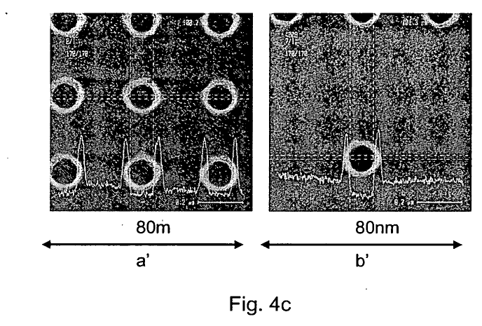

Referring to FIG. 3a, an exposure and developing processes are performed on the photoresist film 103 over an underlying layer 101, thereby obtaining a first photoresist contact hole pattern 105 of 110 nm (see FIGS. 3a and 4a).

The underlying layer is not specifically limited. For example, the underlying layer may include polysilicon, SiO, SiON, or a metal film such as W or Al, for example.

Any suitable chemical amplification-type photoresist can be used as the photoresist film. Preferably, the photoresist has a structure including a methacrylate compound or a cycloolefin compound as a main chain.

Here, a soft baking process is preferably performed before the exposure process, and the post baking process is performed after the exposure process. The baking process is preferably performed at a temperature ranging from about 70° C. to about 200° C.

The exposure process is preferably performed using the light source selected from the group consisting of KrF (248 nm), ArF (193 nm), VUV (157 nm), EUV (13 nm), e-beam, x-ray and ion beam, and the exposure process is preferably performed at an exposure energy ranging from about 0.1 mJ/cm² to about 100 mJ/cm².

The RFP is performed on the first photoresist contact hole pattern 105 of FIG. 3a at a glass transition temperature or over the glass transition temperature of the photoresist for a predetermined time to reduce size of the first photoresist contact hole pattern 105 by 5˜20%. As a result, as shown in FIG. 3b, a photoresist contact hole pattern 105-1 of 100 nm reduced smaller than the first pattern is formed because the amount of resist that can flow in region (a′) having a high contact hole pattern density is small, and a photoresist contact hole pattern 105-2 of 90 nm reduced smaller than the first pattern is formed because the amount of resist that can flow in a region (b′) having a low contact hole pattern density is large (see FIGS. 3b and 4b).

Specific RFP conditions may be properly adjusted with reference to Japanese Journal of Applied Physics (vol. 37 (1998) pp. 6863-6868), the disclosure of which is incorporated herein by reference. Preferably, the RFP is performed at a temperature ranging from about 140° C. to about 170° C. for from about 20 seconds to about 50 seconds.

Then, as shown in FIG. 3c, a coating film 107 is formed on the entire surface of the resulting structure at the same thickness as that of the photoresist film in order to fill the different-sized contact hole patterns 105-1 and 105-2 depending on the above-described pattern density of FIG. 3b.

The coating material is filled into numerous contact holes in the region having a high contact hole pattern density so that the coating film is formed in a low thickness. On the other hand, there are few contact holes to be filled with coating material in the region having a low contact hole pattern density so that the coating film is formed in a high thickness.

After the heating treatment process 109 is performed on the coating film 107, the resulting structure is dipped into water for about 10 seconds to about 120 seconds to remove the coating film 107.

For the coating film, a poly(N,N-dimethylacrylamide) compound having a molecular weight of about 15,000 or a common SAFIER™ material is preferred.

The heating treatment is preferably performed at the glass transition temperature or over the glass transition temperature of photoresist for a predetermined time, e.g., at from about 140° C. to about 170° C. for about 30 seconds to about 120 seconds, so as to reduce the minimum photoresist contact hole pattern obtained from the previous RFP process, e.g., the 90 nm-photoresist contact hole pattern 105-2 by about 5% to about 20%.

The photoresist pattern of 90 nm is reduced to 80 nm in the region (b′), while the photoresist pattern of 100 nm is reduced to 80 nm in the region (a′) because the heat transfer effect is higher by the thin coating film in the region (a′) having a high contact hole pattern density than that of region (b) having a low contact hole pattern density as shown in FIG. 3d. As a result, a second photoresist contact hole pattern 111 reduced to 80 nm regardless of the pattern density is formed by the disclosed method. (see FIGS. 3d and 4c).

Also, there is provided a method for fabricating a semiconductor device that comprises the steps of:

(a) forming a photoresist film over an underlying layer;

(b) performing an exposure and developing process on the photoresist film to form a first photoresist pattern;

(c) performing a coating treatment process on the first photoresist pattern; and

(d) performing an RFP on the resulting structure to obtain a second photoresist pattern having a higher resolution than that of the first photoresist pattern.

The coating treatment process of step (c) preferably includes forming a coating film over the resulting structure of step (b); performing the heating treatment process thereon; and removing the coating film.

The RFP is preferably performed at the glass transition temperature or over the glass transition temperature of photoresist. The heating treatment process of the coating treatment process is performed at a glass transition temperature or over the glass transition temperature of the photoresist.

The second disclosed method is described in detail with reference to the attached drawings.

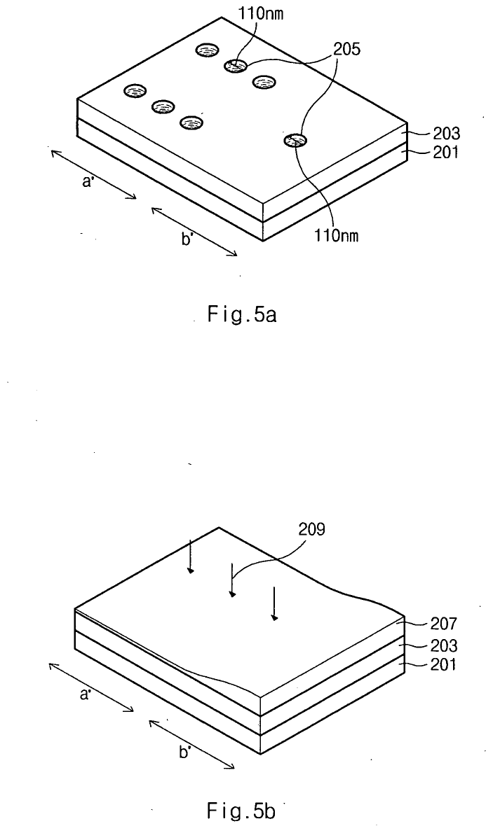

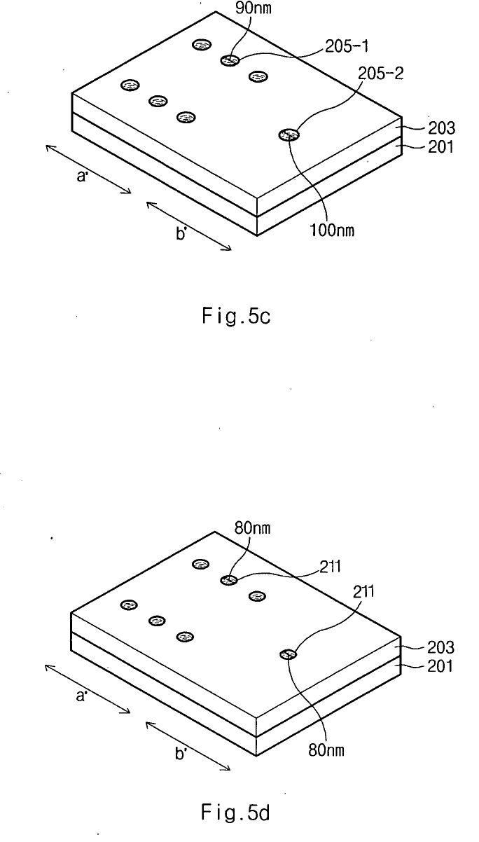

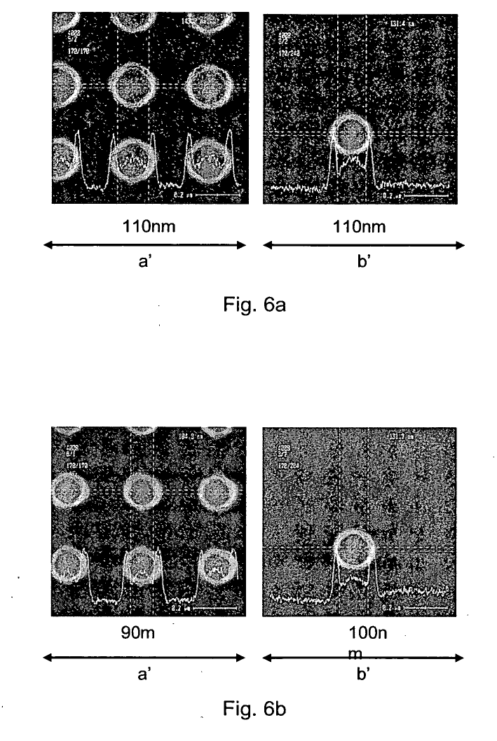

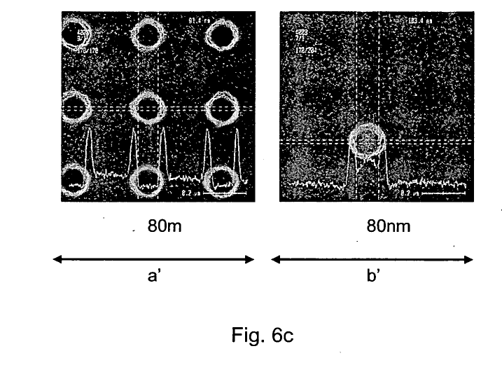

Referring to FIG. 5a, an exposure and developing process is performed on the photoresist film 203 over an underlying layer 201, thereby obtaining a first photoresist contact hole pattern 205 of 110 nm (see FIGS. 5a and 6a).

As shown in FIG. 5b, a coating film 205 is coated over the resulting structure at the same thickness as that of the photoresist film to fill the first photoresist contact hole pattern 203. After the heating treatment process 209 is performed on the coating film 207 at a glass transition temperature of the of photoresist, and dipped into water for a predetermined time to remove the coating film 207 as shown in FIG. 5c.

When the coating material is a poly(N,N-dimethylacrylamide) compound having a molecular weight of 15,000, the heating treatment process is preferably performed at a glass transition temperature or over the glass transition temperature of photoresist for a predetermined time to reduce the first photoresist contact hole pattern 203 by about 5% to about 20%. For example, when the heating treatment process is performed at from about 140° C. to about 170° C. for about 30 seconds to about 120 seconds, a contact hole pattern 205-1 of 90 nm reduced smaller than the first pattern is formed in a region (a′) having a high contact hole pattern density, and a contact hole pattern 205-2 of 100 nm reduced smaller than the first pattern is formed in a region (b′) having a low contact hole pattern density (see FIGS. 5c and 6b).

Thereafter, the RFP is performed on the different-sized contact hole patterns 205-1 and 205-2 at a glass transition temperature of photoresist depending on the pattern density.

The RFP process is preferably performed at the glass transition temperature or over the glass transition temperature of photoresist for a predetermined time, e.g., at from about 140° C. to about 170° C. for about 30 seconds to about 120 seconds, so as to reduce the minimum photoresist contact hole pattern obtained from the previous coating treatment process, e.g., the 90 nm photoresist contact hole pattern 205-1 by about 5% to about 20%.

As shown in FIG. 5d, the 100 nm contact hole pattern formed in the region (b′) having a low contact hole pattern density is reduced to 80 nm, and the 90 nm pattern formed in the region (a′) having a high contact hole pattern density is relatively less reduced to 80 nm. As a result, a second photoresist contact hole pattern 213 reduced to 80 nm regardless of the pattern density is formed (see FIGS. 5d and 6c).

Additionally, there is provided a semiconductor device fabricated by the above-described methods for fabricating a semiconductor device.

The disclosed patterns will be described in detail by referring to examples below, which are not intended to be limiting of this disclosure.

I. Preparation of a Disclosed Coating Material

### PREPARATION EXAMPLE 1

Poly(N,N-dimethylacrylamide) (produced by Aldrich. Co., glass transition temperature of 157° C.) having a molecular weight of 15,000 (10 g) was dissolved in distilled water (120g) to obtain a disclosed coating material.

II. Formation of a Disclosed Pattern

### EXAMPLE 1

An oxide film as underlying layer was formed on a silicon wafer treated with HMDS, and a methacrylate type photoresist (Tarf-7a-39 produced by TOK Co., glass transition temperature of 154° C.) was spin-coated thereon and was soft-baked at about 130° C. for about 90 seconds to form a photoresist film at a thickness of 3,500 Å. After baking, the photoresist film was exposed to light using an ArF exposer, and post-baked at about 130° C. for about 90 seconds. When the post-baking was completed, it was developed in 2.38 wt % tetramethylammonium hydroxide(TMAH) solution for about 30 seconds, to obtain a 110 nm first photoresist contact hole pattern (see FIG. 4a).

Thereafter, the first photoresist contact hole pattern was baked at 154° C. for about 30 seconds to flow the photoresist. As a result, a 100 nm photoresist contact hole pattern was formed in the region (a′) having a high contact hole pattern density, and a 90 nm photoresist contact hole pattern was formed in the region (b′) having a low contact hole pattern density (see FIG. 4b).

Next, the coating material obtained from Preparation Example 1 was spin-coated at 3,500 Å on the whole surface of the photoresist contact hole pattern. Then, the resulting structure was heated at 157° C. for about one minute, and dipped into water for about 40 seconds to remove the coating film. As a result, a second photoresist contact hole pattern reduced to 80 nm was formed in both regions having a high contact hole pattern density and a low contact hole pattern density (see FIG. 4c).

### EXAMPLE 2

An oxide film as underlying layer was formed on a silicon wafer treated with HMDS, and the methacrylate type photoresist used in Example 1 was spin-coated thereon and was soft-baked at about 130° C. for about 90 seconds to form a photoresist film at a thickness of 3,500 Å. After baking, the photoresist film was exposed to light using an ArF exposer, and post-baked at about 130° C. for about 90 seconds. When the post-baking was completed, it was developed in 2.38 wt % TMAH solution for about 30 seconds, to obtain a 110 nm first photoresist contact hole pattern (see FIG. 6a).

Next, the coating material obtained from Preparation Example 1 was spin-coated at 3,500 Å on the whole surface of the photoresist contact hole pattern. Then, the resulting structure was heated at 157° C. for about one minute, and dipped into water for about 40 seconds to remove the coating film. As a result, a 90 nm photoresist contact hole pattern was formed in the region (a′) having a high contact hole pattern density, and a 100 nm photoresist contact hole pattern was formed in the region (b′) having a low contact hole pattern density (see FIG. 6b).

Then, a resist flow process was performed on the entire surface of the contact hole pattern at 154° C. for about 30 seconds to obtain a second contact hole pattern reduced to 80 nm in both regions having a high contact hole pattern density and a low contact hole pattern density (see FIG. 6c).

### EXAMPLE 3

An oxide film as underlying layer was formed on a silicon wafer treated with HMDS, and a cycloolefin type ArF photoresist (GX02 produced by Dongin Semichem Co., glass transition temperature of 162° C.) was spin-coated thereon and was soft-baked at about 130° C. for about 90 seconds to form a photoresist film at a thickness of 3,500 Å. After baking, the photoresist film Was exposed to light using an ArF exposer, and post-baked at about 130° C. for about 90 seconds. When the post-baking was completed, it was developed in 2.38 wt % TMAH solution for about 30 seconds, to obtain 110 nm first photoresist contact hole pattern.

Thereafter, the first photoresist contact hole pattern was baked at 162° C. for about 30 seconds to flow the photoresist. As a result, a 100 nm photoresist contact hole pattern was formed in the region having a high contact hole pattern density, and a 90 nm photoresist contact hole pattern was formed in the region having a low contact hole pattern density.

Next, the coating material obtained from Preparation Example 1 was spin-coated at 3,500 Å on the entire surface of the photoresist contact hole pattern. Then, the resulting structure was heated at 157° C. for about one minute, and dipped into water for about 40 seconds to remove the coating film. As a result, a second contact hole pattern reduced to 80 nm was formed in both regions having a high contact hole pattern density and a low contact hole pattern density.

### EXAMPLE 4

An oxide film as underlying layer was formed on a silicon wafer treated with HMDS, and the cycloolefin type ArF photoresist used in Example 3 was spin-coated thereon and was soft-baked at about 130° C. for about 90 seconds to form a photoresist film at a thickness of 3,500 Å. After baking, the photoresist film was exposed to light using an ArF exposer, and post-baked at about 130° C. for about 90 seconds. When the post-baking was completed, it was developed in 2.38 wt % TMAH solution for about 30 seconds, to obtain a 110 nm first photoresist contact hole pattern.

Next, the coating material obtained from Preparation Example 1 was spin-coated at 3,500 Å on the entire surface of the photoresist contact hole pattern. Then, the resulting structure was heated at 157° C. for about one minute, and dipped into water for about 40 seconds to remove the coating film. As a result, 90 nm photoresist contact hole pattern was formed in the region having a high contact hole pattern density, and 100 nm photoresist contact hole pattern was formed in the region having a low contact hole pattern density.

Then, a resist flow process was performed on the entire surface of the contact hole pattern at 162° C. for about 30 seconds to obtain a second contact hole pattern reduced to 80 nm in both regions having a high contact hole pattern density and a low contact hole pattern density.

As described above, a photoresist pattern is formed, and RFP and coating treatment process are performed thereon, thereby obtaining a photoresist pattern reduced to the same size of more than a resolution of an exposer regardless of pattern density.

What is claimed is:

1. A method for fabricating a semiconductor device using a photolithography process, comprising:
(a) forming a first photoresist pattern from a photoresist composition; and
(b) performing both a resist flow process (RFP) and a coating treatment process to obtain a second photoresist pattern having a higher resolution than that of the first photoresist pattern.

2. The method of claim 1, comprising:
(i) forming a photoresist film over an underlying layer;
(ii) performing an exposure and developing process on the photoresist film to form a first photoresist contact hole pattern;
(iii) performing a resist flow process on the first photoresist contact hole pattern; and
(iv) performing a coating treatment process on the whole surface of the resulting structure to obtain a second photoresist pattern.

3. The method of claim 2, wherein the photoresist film includes a methacrylate compound or a cycloolefin compound.

4. The method of claim 1, comprising:
(i) forming a photoresist film over an underlying layer;
(ii) performing an exposure and developing process on the photoresist film to form a first photoresist contact hole pattern;
(iii) performing a coating treatment process on the first photoresist contact hole pattern; and
(iv) performing a resist flow process on the whole surface of the resulting structure to obtain a second photoresist pattern.

5. The method of claim 4, wherein the photoresist film includes a methacrylate compound or a cycloolefin compound.

6. The method of claim 1, comprising performing the resist flow process above the glass transition temperature (Tg) of the photoresist polymer.

7. The method of claim 6, comprising performing the resist flow process under conditions to reduce the photoresist pattern by 5% to 20% of the minimum size of the photoresist pattern obtained from the previous step.

8. The method of claim 1, wherein the coating treatment process comprises the steps of;
forming a coating film over the resulting structure of the previous step;
performing a heating treatment process thereon; and
removing the coating film.

9. The method of claim 8, wherein the dissolution property of the coating film is different from that of the photoresist polymer.

10. The method of claim 9, wherein the coating film comprises a SAFIER™ material or a water-soluble polymer compound having a molecular weight ranging from 200 to 50,000.

11. The method of claim 10, wherein the water-soluble polymer compound is a poly(N,N-dimethylacrylamide) compound having a molecular weight of 15,000.

12. The method of claim 8, comprising performing the heating treatment process of the coating treatment process over the glass transition temperature of the photoresist polymer.

13. The method of claim 12, comprising performing the heating treatment process of the coating treatment process under conditions to reduce the photoresist pattern by about 5% to about 20% of the minimum size of the photoresist pattern obtained from the previous step.

14. The method of claim 8, comprising performing the removing step using water.

15. The method of claim 1, wherein the resolution of the second photoresist pattern is higher than the resolution of the photoresist pattern obtained by using an exposer.

16. A semiconductor device fabricated by the method of claim 1.
